(19) United States
(12) Patent Application Publication
(10) Pub. No.: US 2012/0202324 A1
(43) Pub. Date: Aug. 9, 2012

(54) MANUFACTURING APPARATUS OF SEMICONDUCTOR DEVICE AND PATTERN-FORMING METHOD

(75) Inventors: Fuminori TATEISHI, Atsugi (JP); Hideaki Kuwabara, Isehara (JP)

(73) Assignee: SEMICONDUCTOR ENERGY LABORATORY CO., LTD., Atsugi-shi (JP)

(21) Appl. No.: 13/451,694

(22) Filed: Apr. 20, 2012

Related U.S. Application Data
(62) Division of application No. 12/502,331, filed on Jul. 14, 2009.
Application No. 12/502,331 is a division of application No. 11/119,964, filed on May 3, 2005, now abandoned.

(30) Foreign Application Priority Data
May 21, 2004 (JP) 2004-151859

(51) Int. Cl. H01L 21/336; H01L 21/28

(52) U.S. Cl. 438/158; 438/585; 257/E21.411; 257/E21.177

(57) ABSTRACT

The present invention provides a manufacturing apparatus of a semiconductor device, having a pattern-forming apparatus using a droplet-discharging method that is suitable for a large substrate in mass production. A plurality of pattern-forming apparatuses using a droplet-discharging method and a plurality of heat-treatment chambers are provided, and each of which is connected to one transfer chamber, which is a multi-chamber system. Discharging and baking are conducted efficiently to improve productivity. A gas is blown in the same direction as the scanning direction (or a scanning direction of a discharging head) on a substrate just after a droplet is landed, by providing a blowing means in the pattern-forming apparatus, and a heater is provided in a gas-flow path for local baking.

### BACKGROUND OF THE INVENTION

1. Field of the Invention

The present invention relates to a pattern-forming method in which a composition containing a material of an object to be formed is dropped (typically, a method for forming a wiring), and a manufacturing apparatus of a semiconductor device having a circuit including a thin film transistor (TFT).

Specifically, the present invention relates to a pattern-forming method of a wiring by a droplet-discharging method (such as an ink jet method) and a manufacturing apparatus of a semiconductor device having a TFT.

A semiconductor device in this specification means a general device that can operates by using a semiconductor property, and includes an electro-optic device, a light-emitting device, a semiconductor circuit and an electronic device.

2. Description of the Related Art

Conventionally, a film-formation method using a spin-coating method is frequently employed in a manufacturing process.

A droplet-discharging technique typified by a piezo method or a thermal jet method, or a continuous droplet-discharging technique has attracted attention. This droplet-discharging technique has been used for printing words and drawing an image. However, an attempt to apply the droplet-discharging technique to a semiconductor field, for example, micropattern formation or the like has been made in recent years.

This applicant has described in Reference 1 that an ink jet method is used in one chamber of a multi-chamber for forming an EL element (Reference 1: Japanese Patent Laid-Open No. 2001-345174).

### SUMMARY OF THE INVENTION

In manufacturing an electronic device having a semiconductor circuit, a gang-printing that is a manufacturing method of cutting out plural devices from one mother glass for mass-producing efficiently is employed without using a silicon wafer. The size of a mother glass substrate is increased from 300 mm×400 mm of the first generation in the early 1990s to 680 mm×880 mm or 730 mm×920 mm of the fourth generation in 2000. Furthermore, the manufacturing technique has been developed so that a large number of devices, typically, display panels can be obtained from one substrate.

When the substrate size is further increased in a future, the spin-coating method as the film-formation method becomes disadvantageous in mass production, because a rotation mechanism for rotating a large substrate becomes large and there is loss of a material solution or much waste liquid. When a rectangular substrate is spin-coated, a coated film tends to be rough, that is, the coated film tends to have a circular uneveness with the rotation axis as the center.

The present invention provides a manufacturing apparatus of a semiconductor device, having a pattern-forming apparatus using a droplet-discharging method that is suitable for a large substrate in mass production.

According to the present invention, a plurality of pattern-forming apparatuses using a droplet-discharging method and a plurality of heat-treatment chambers are provided, and each of which is connected to one transfer chamber, which is a multi-chamber system. Therefore, discharging and baking are conducted efficiently to improve productivity. In the case of an in-line system in mass-production, when a pattern-forming apparatus having one chamber using a droplet-discharging method is used, it is necessary to conduct bake treatments plural times after discharging a material solution selectively by a droplet-discharging method. Thus, there is a fear that the productivity is more decreased in the in-line system than in a multi-chamber system.

When using a stage that is movable in an X direction or Y direction, or a droplet-discharging head that is movable in an X direction or Y direction, it is more difficult to conduct a precise alignment than when using a stage or a droplet-discharging head that is movable in only one direction, and further the apparatus itself becomes expensive. For this reason, the present invention provides a pattern-forming apparatus using a droplet-discharging method in which scanning can be conducted in only one direction (an X direction or Y direction) of a large substrate so as to simplify a structure of the apparatus. For example, in order to form a branching pattern or a bended and curved pattern of a wiring, a first pattern-forming apparatus for scanning in an X direction and a second pattern-forming apparatus for scanning in a Y direction are employed. In this manner, productivity can be enhanced.

In addition, the first pattern-forming apparatus and the second pattern-forming apparatus are arranged to conduct a treatment with the direction of a large substrate unchanged. Therefore, a transferring means can be simplified and the transferring time can be shortened. Further, pattern-forming in a transfer path is also preferably conducted without rotating a large substrate.

A pattern-forming apparatus using a droplet-discharging method has a problem in that the difference in time during exposure to the air between a portion where a pattern is formed first by discharging droplets and a portion where a pattern is formed last by discharging droplets, becomes larger, as the size of a substrate is larger. There is a risk that degree of baking is different due to the larger difference in time and thus a uniform pattern-forming is difficult.

Further, a pattern-forming apparatus using a droplet-discharging method has a problem in that the alignment of a position where a droplet is discharged and landed becomes unstable due to airflow generated by moving a stage or a head in a treatment chamber.

In view of the above problems, according to the present invention, a gas is blown in the same direction as the scanning direction (or a scanning direction of a discharging head) on a substrate just after a droplet is landed, by providing a blowing means, and local baking is performed by providing a heater.

One of structures of the present invention disclosed in this specification is a manufacturing method of a semiconductor device having a treatment chamber including a droplet-discharging means for forming a pattern selectively over a substrate by discharging droplets (also referred to as dots) containing a pattern-forming material; a blowing means for controlling a flight-trajectory of the discharged droplets; a heating means provided in a flow path of a gas airflow blown from a gas-outlet of the blowing means; and a controlling means for controlling the droplet-discharging means, the blowing means and the heating means.

In the above described structure, the heating means is a heater having a resistant heating element that is string-like, wire-like, coil-like, stick-like or planar.

According to the above described structure, a droplet is landed. After a certain time, a temporary baking is conducted, thereby obtaining a uniform pattern, even if difference in time during exposure to the air between a portion where a pattern is formed first by discharging droplets and a portion where a pattern is formed last by discharging droplets, becomes larger. For example, a pattern can be formed efficiently on a substrate with the large size of 600 mm×720 mm, 680 mm×880 mm, 1000 mm×1200 mm, 1100 mm×1250 mm, or 1150 mm×1300 mm. In addition, since a heater is provided in a gas flow path, rapid-heating or cooling for a pattern of a landed material can be prevented. Note that a gas is preferably blown at an angle in the same direction as the scanning direction on the substrate so that the gas is not blown onto a discharging head. The total time of baking can be shortened by conducting a heat treatment in a treatment chamber after discharging.

A heater may be provided for a stage to heat a substrate so as to reduce the total time of baking.

In the pattern-forming apparatus using a droplet-discharging method, the heater and the discharging head are preferably provided at a certain space therebetween, because the discharging head is sensitive to temperature or humidity of the atmosphere in the vicinity. When a high temperature gas is blown from a nozzle, the nozzle is also heated. At this time, the temperature in the vicinity of the discharging head is increased to cause the nozzle to be clogged. If the discharging head and the nozzle are unified, it is preferable that a heat-insulating material is provided between the discharging head and the nozzle so as to prevent heat from the nozzle from being conducted to the discharging head or to prevent heat from the discharging head from being conducted to the nozzle. A gas-outlet of the nozzle is preferably linear.

In order to control a complicated airflow (airflow generated by moving the stage or the head in a treatment chamber), it is preferable that a constant airflow is generated in the whole treatment chamber by a blowing means and the airflow is controlled in the same direction as the scanning direction. A pattern can be formed more stably by generating the constant airflow for canceling airflow generated by moving the stage or the head in the treatment chamber.

In the above described structure, an exhausting means is provided downstream of the airflow of a gas blown from the gas-outlet of the blowing means. By providing the exhausting means, the pressure of the treatment chamber is controlled and at the same time, a constant airflow is generated in the whole treatment chamber.

In addition, a plurality of blowing means may be provided to generate a constant airflow in the whole treatment chamber, or a guide for controlling the airflow may be provided in the treatment chamber.

One of structures of the present invention disclosed in this specification is a manufacturing apparatus of a semiconductor device comprising: a first treatment chamber having a droplet-discharging means for forming a pattern selectively over a substrate by discharging droplets containing a pattern-forming material, a blowing means for controlling a flight-trajectory of the discharged droplets, and a controlling means for controlling the droplet-discharging means and the blowing means; a second treatment chamber having a heating means; a transfer chamber connected to the first treatment chamber and the second treatment chamber.

In the above described structure, a multi-chamber system is employed in which the transfer chamber is connected to a plurality of first treatment chambers and a plurality of second treatment chambers.

In generating a constant airflow by the blowing means in the whole treatment chamber, it is preferable to provide a plurality of pattern-forming apparatuses using a droplet-discharging method, in which scanning is conducted in one direction (an X direction or Y direction) of a large substrate. Another structure of the present invention is a manufacturing apparatus of a semiconductor device comprising: a first treatment chamber having a first droplet-discharging means for forming a pattern in an X direction over a substrate by discharging droplets containing a pattern-forming material, a first blowing means for controlling a flight-trajectory of the discharged droplets in the X direction of the substrate, and a first controlling means for controlling the first droplet-discharging means and the first blowing means; a second treatment chamber having a second droplet-discharging means for forming a pattern in a Y direction over a substrate by discharging droplets containing a pattern-forming material, a second blowing means for controlling a flight-trajectory of the discharged droplets in the Y direction of the substrate, and a second controlling means for controlling the second droplet-discharging means and the second blowing means; and a transfer chamber connected to the first treatment chamber and the second treatment chamber.

In the above described structure, the direction of the substrate is unchanged in the first treatment chamber, the transfer path from the first treatment chamber to the second treatment chamber, and the second treatment chamber. If a pattern formed by a droplet-discharging method is not dried sufficiently, a large substrate is rotated and thus a centrifugal force is applied to the fringe portion of the substrate. Thus, since there is a risk that the pattern form is deformed, the direction of the substrate is preferably unchanged during all treatments and transferring of the substrate.

In the above described structure, a measuring means is provided to measure the amount of droplets discharged from the droplet-discharging means. A more precise pattern can be formed by measuring the amount of droplets and controlling the conditions of discharging.

A pattern-forming method is also one feature of the present invention. The pattern-forming method comprising the steps of: when selectively forming a pattern by discharging droplets containing a pattern-forming material over a substrate by a droplet-discharging means, changing by a blowing means a flight-trajectory of the discharged droplets from the droplet-discharging means; blowing a gas onto the discharged droplets by the blowing means to dry the discharged droplets; and heating the gas by a heating means provided in a portion of a flow path of the blown gas to bake a lower region of a flow path of the heated gas.

The shape of a pattern can be controlled by adjusting airflow of a gas and by changing a flight-trajectory of droplets by drawing droplets discharged from the discharging head to the side of the blowing means. Another structure of the present invention is that a pattern-forming method comprising the step of: when selectively forming a pattern by discharging droplets containing a pattern-forming material over a substrate by a droplet-discharging means, controlling a shape of a pattern by changing a flight-trajectory of droplets that are discharged from the droplet-discharging means by adjusting a flow rate of a blowing means at the same time as discharging the droplets.

For example, in order to prevent droplets from being accumulated at a start point of drawing a linear pattern, a scan is performed with a gas flow rate increased from zero. At this time, the extra droplets are extended in the scanning direction. The gas flow rate is reduced to zero as it gets closer to an end-point of the linear pattern drawing while scanning, thereby obtaining a liner pattern having a uniform width. In other words, according to the present invention, a portion of a pattern is formed by changing a flight-trajectory of a droplet by increasing and decreasing (adjusting) the amount of a gas by the blowing means, without moving the discharging head or the stage.

Further, a flight-image of a droplet can be imaged by changing a flight-trajectory of a droplet with airflow, and droplets can be discharged while measuring the amount of droplets to be discharged. Another structure of the present invention is that a pattern-forming method comprising the step of: when selectively forming a pattern by discharging droplets containing a pattern-forming material over a substrate by a droplet-discharging means, changing by a blowing means a flight-trajectory of the discharged droplets from the droplet-discharging means; and adjusting the droplet-discharging means and the blowing means while measuring an amount of the droplets by imaging flying droplets.

Note that another imaging means for aligning is separately provided in addition to the imaging means for measuring the amount of droplets.

By providing the imaging means in the vicinity of the head, a flight-image of droplets can be imaged from the side of the head (from above the substrate), and the imaged picture is processed to obtain the size of the image. With the size of the image, the volume of droplets can be calculated. In a conventional manner, because a droplet is discharged toward a substrate directly under the head from a discharging port of a discharging head, it is difficult to image a picture even if an imaging means is provided adjacently with the discharging head. According to the present invention, since a droplet is dropped from an angle toward a substrate from a discharging port of a discharging head, the flying droplet can be imaged from above when the imaging means is provided adjacently with the discharging head.

An inert gas typified by nitrogen, air or a dry gas thereof is used as the gas blown from the blowing means. The temperature of the gas blown from the blowing means is set higher in the vicinity of the heater than that of the gas in the gas-outlet. For example, the temperature of the gas in the gas-outlet is preferably keptroom-temperature or a constant temperature that is lower than 100° C. The temperature of the gas is preferably a baking-temperature (100 to 300° C.) by the heater for heating arranged in the gas flow path. Moreover, a controlling means for controlling humidity or temperature may be provided in the treatment chamber.

When a pattern is formed by using a material solution that is easily dried, a low-temperature gas (0 to −50° C.) or a gas containing much moisture or a constituent that volatilizes a solvent may be blown by a blowing means to prevent rapid drying, or a low-temperature gas (0 to −50° C.) may be blown by arranging a cooling element (such as a peltiert element) in the gas flow path. Since the temperature of an inert gas stored in a compressed cylinder is lower than a room temperature, the gas can be introduced without being cooled.

In addition to the blowing means, an atmospheric plasma means, or a light-irradiation means such as a UV lamp, a halogen lamp, or a flash lamp may be provided in the treatment chamber for cleaning a surface of a substrate and modifying the surface. Before discharging a droplet, a blowing means or an exhausting means for removing minute dusts on a substrate may be provided.

As a material for forming a pattern, gold (Au), silver (Ag), copper (Cu), platinum (Pt), palladium (Pd), tungsten (W), nickel (Ni), tantalum (Ta), bismuth (Bi), lead (Pb), indium (In), tin (Sn), zinc (Zn), titanium (Ti) or aluminium (Al), or an alloy including any of the elements, dispersed nanoparticles thereof, or fine particle of silver halide can be employed. In particular, low-resistant silver or copper is preferably used. As other materials for forming a pattern, indium tin oxide (ITO), IZO in which zinc oxide (ZnO) of 2 to 20% is mixed into indium oxide, ITSO in which silicon oxide (SiO₂) of 2 to 20% is mixed into indium oxide, organic indium, organotin, titanium nitride (TiN) or the like can be used. The present invention is suitable for forming wirings having a branching pattern, a T-like pattern, an L-like pattern or the like.

For example, a material in a liquid condition in which organic indium and organotin are mixed with a ratio of 99:1 to 90:10 in xylole is discharged onto the substrate by a droplet-discharging method and heated to form a pattern containing ITO.

According to the present invention, a conductive layer constituting a part of a semiconductor device can be formed by a droplet-discharging method. One feature of the present invention is that a pattern of a wiring is formed by a dropping method typified by an ink-jet method. Typically, any of a gate electrode, a source electrode, a drain electrode, and wirings connected to the electrodes in a thin film transistor are formed by a dropping method typified by an ink-jet method.

Note that a structure and the like of a thin film transistor in which a wiring is formed by a dropping method are not limited. In other words, a thin film transistor may have either a crystalline semiconductor film or a non-crystal semiconductor film and may be either a bottom gate type (channel-etch type or channel-protective type) in which a gate electrode is formed under a semiconductor film or a top gate type in which a gate electrode is formed over a semiconductor film.

According to the present invention, a composition (including a composition dissolved or dispersed with a conductor in a solvent) mixed with a conductor (a material for forming a wiring) in a solvent is discharged to form a wiring. Specifically, when a wiring is formed by an ink jet method, a photolithography process such as light-exposure or development of a mask for patterning the wiring, and an etching process for patterning the wiring can be omitted.

The present invention is not limited to such conductive materials in particular. An insulating material can be used as the pattern-forming material, and thus, a pattern of an insulator can be formed.

At this time, the pattern-forming material is discharged to be a dot shape (droplet) or a pillar shape by a series of dots; however, they are collectively referred to as a dot (droplet). Discharging a dot (droplet) means that a dot-like droplet or a pillar-like droplet is discharged. In other words, since a plurality of dots are discharged continuously, a pillar-like (dot) droplet is discharged in some cases without being recognized as a dot.

According to the present invention, a uniform pattern can be formed over a large substrate with a pattern-forming apparatus by using a droplet-discharging method, and at the same time, a tact time in manufacturing a semiconductor device can be shortened.

A large number of devices can be manufactured from a glass substrate from the fifth generation onward, which is 1000 mm×1300 mm, 1000 mm×1500 mm, or 1800 mm×2200 mm, namely has one side more than 1 m, and therefore, the price of a device can be expected to be lowered. In this case, it is possible to build a production line which can maintain profitability by employing a dropping method typified by an ink-jet method. This is because a photo process can be simplified by forming a wiring or the like by a dropping method typified by an ink-jet method. Consequently, a photo mask becomes unnecessary, and reduction of costs such as a facility investment cost can be achieved.

Further, manufacturing time can be shortened because a photolithography process becomes unnecessary. Efficiency in the use of materials improves, and a cost and an amount of waste liquid can be reduced by using a dropping method typified by an ink-jet method. It is effective that a dropping method typified by an ink-jet method is applied to a large-are substrate in this way.

### BRIEF DESCRIPTION OF THE DRAWINGS

In the accompanying drawings:

FIG. 1 is a top view showing an example of a manufacturing apparatus according to the present invention (Embodiment Mode 1);

FIG. 2 is a cross-sectional view showing a pattern-forming treatment chamber (Embodiment Mode 1);

FIGS. 3A to 3C each show a method for forming a pattern according to the present invention (Embodiment Mode 2);

FIG. 4 is a cross-sectional view of a pattern-forming treatment chamber (Embodiment Mode 3);

FIG. 5 is a perspective view of a pattern-forming treatment system (Embodiment Mode 3);

FIGS. 6A to 6E are each a cross-sectional view showing manufacturing steps of a thin film transistor (Embodiment Mode 4);

FIGS. 7A to 7C are each a cross-sectional view showing of a thin film transistor and a pixel electrode (Embodiment Mode 5);

FIG. 8 is a cross-sectional view of a liquid crystal module (Embodiment Mode 6);

FIGS. 9A and 9B are an equivalent circuit and a top view of a light-emitting device, respectively (Embodiment Mode 7);

FIG. 10 is a cross-sectional view of a pixel in a light-emitting device (Embodiment Mode 7);

FIGS. 11A to 11C are each a top view showing a structure of a display panel as examples;

FIGS. 12A to 12E each show an example of electronic devices; and

FIG. 13 shows an example of an electronic device.

### DETAILED DESCRIPTION OF THE INVENTION

Embodiment Modes according to the present invention will hereinafter be described with reference to the accompanying drawings. The present invention can be carried out in many different modes, and it is easily understood by those skilled in the art that modes and details herein disclosed can be modified in various ways without departing from the spirit and the scope of the present invention. It should be noted that the present invention should not be interpreted as being limited to the description of the embodiment modes to be given below.

### Embodiment Mode 1

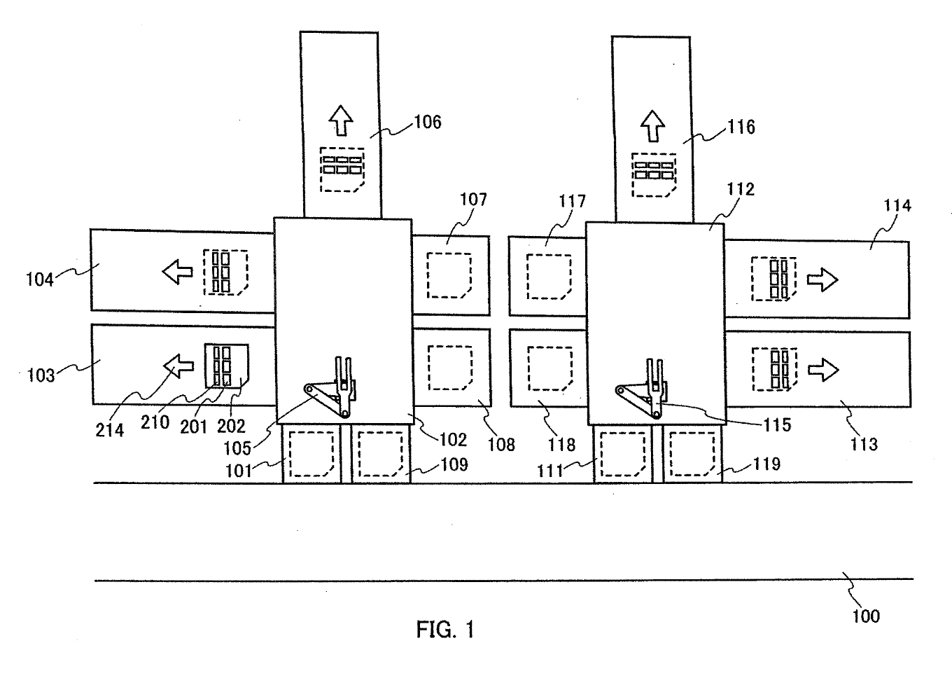

Embodiment Mode 1 shows a manufacturing apparatus using an ink-jet apparatus (a droplet-discharging apparatus) having a blowing means as one chamber of multi-chamber with reference to FIG. 1.

The manufacturing apparatus shown in FIG. 1 includes a substrate load chamber 101 that is connected to a transfer path 100, a transfer chamber 102 that is connected to the substrate load chamber 101, pattern-forming chambers 103, 104 and 106 that are connected to the transfer chamber 102, multi-stage heating chambers 107 and 108 that are connected to the transfer chamber 102, and a substrate unload chamber 109 that is connected to the transfer chamber 102.

Hereinafter, a flow of treating a substrate and transferring it is shown. Note that an example of forming patterns of a gate wiring and a gate electrode that branches from the gate wiring is shown here.

Large substrates transferred from the transfer path 100 are set in the substrate load chamber 101 with the substrates contained in an cassette which is capable of containing a plurality of substrates. All of the large substrates that are set are contained facing the same direction.

A large substrate 202 of the large substrates is transferred into the pattern-forming treatment chamber 103 from the substrate load chamber 101 through the transfer chamber 102 by a transferring robot 105 provided in the transfer chamber 102. Note that the transferring robot 105 can freely move in the transfer chamber 102. In the pattern-forming treatment chamber 103, a droplet-discharging means 201 and a blowing means 210 are shown.

Further, the substrate that has been transferred into the pattern-forming treatment chamber 103 passes under the droplet-discharging means with the substrate held by a stage that is movable in one direction. While the substrate is passing under the droplet-discharging means, droplets containing a conductive material are discharged and a gas is blown in an X direction of the substrate 202. At this time, a gate wiring extending in the X direction is formed over the substrate. The stage is moved in the same direction as a direction 214 of airflow formed by the blowing means to form a pattern. Here, the example of moving the stage is shown; however, the discharging head and the blowing means may be moved with the stage fixed.

A heater is incorporated in the stage to heat the substrate while discharging droplets so as to shorten the time needed for baking.

Three droplet-discharging means and three blowing means are provided in one treatment chamber 103, and the total width of the plurality of droplet-discharging means are set to become equal to or wider than the width of the substrate; however, the present invention is not limited to this structure in particular, and one droplet-discharging means having the width equal to or wider than that of the substrate may be used. When a large substrate is used, three or more droplet-discharging means are preferably set.

After forming a pattern in the X direction, the substrate is carried out from the pattern-forming treatment chamber 103 and transferred into the pattern-forming treatment chamber 106 without turning the direction of the substrate. A pattern is formed in the Y direction in the pattern-forming treatment chamber 106. The substrate that has been transferred in the pattern-forming treatment chamber 106 passes under the droplet-discharging means with the substrate held by a stage that is movable in the Y direction. Droplets containing a conductive material are discharged and a gas is blown in the Y direction of the substrate while the substrate is passing under the droplet-discharging means. At this time, a gate electrode is formed in the Y direction over the substrate, and a gate wiring unified with the gate electrode is formed.

The wiring pattern is cooled by the blowing means in the pattern-forming treatment chamber 103 to prevent drying, and the substrate is transferred into the pattern-forming treatment chamber 106 without turning the direction of the substrate. After discharging the droplets, the unified wiring pattern may be heated to be dried by the blowing means in the pattern-forming treatment chamber 106. This method is effective for forming a branching or crossing wiring by discharging droplets of the same material that is difficult to be overlapped with each other when dried, in a plurality of treatment chambers.

The width of the gate wiring is set to become wider than that of the gate electrode in many cases, and the conditions for droplet-discharging (such as the amount of droplets or nozzle diameter) are also different when the widths are different. Thus, it is effective that the gate electrode and the gate wiring are formed by using the plurality of the pattern-forming treatment chambers. The structure of the apparatus can be simplified by using a pattern-forming treatment chamber for scanning in only one direction.

The substrate is transferred into the multi-stage heating chamber 107 and baked without turning the direction of the substrate. A plurality of substrates are heated uniformly with a plate heater (typically, a sheath heater) in the multi-stage heating chamber 107. A plurality of such plate heaters are arranged. The opposite sides of the substrate can be heated by being sandwiched between the plate heaters, or of course, one side of the substrate may be heated.

After baking is finished, the substrate is transferred into the substrate unload chamber 109 through the transfer chamber 102. At this time, it becomes possible to transfer the substrate through the transfer path 100 into a treatment chamber where the next treatment is conducted.

The multi-stage heating chamber 108 and the pattern-forming treatment chamber 104 are also connected to the transfer chamber 102. The tact time can be shortened by using the plurality of pattern-forming treatment chambers and the plurality of the multi-stage heating chambers. The heating temperature of the multi-stage heating chamber 108 may be different from that of the multi-stage heating chamber 107. Droplets containing a conductive material are discharged and a gas is blown in the X direction of the substrate in the pattern-forming treatment chamber 104. Note that the numbers of the multi-stage heating chambers and the pattern-forming treatment chamber that are each connected to the transfer chamber 102 are not limited to the structure shown in FIG. 1.

FIG. 1 shows one more multi-chamber type manufacturing apparatus connected to the transfer path 100. In the one more multi-chamber type manufacturing apparatus, the same treatment can be conducted. The multi-chamber type manufacturing apparatus includes a substrate load chamber 111 that is connected to the transfer path 100, a transfer chamber 112 that is connected to the substrate load chamber 111, pattern-forming treatment chambers 113, 114 and 116 that are connected to the transfer chamber 112, multi-stage heating chambers 117 and 118 that are connected to the transfer chamber 112, and a substrate unload chamber 119 that is connected to the transfer chamber 112. A transferring robot 115 is provided in the transfer chamber 112.

As shown in FIG. 1, the multi-chamber type manufacturing apparatuses are arranged so that the multi-stage heating chambers are adjacent to each other so as to control airflow. Accordingly, the airflow in the whole apparatus directs outside. In the case where a heating chamber exists downstream of the airflow in the pattern-forming treatment chamber, there is a risk that the airflow in the pattern-forming treatment chamber is changed because of temperature increase due to the heating chamber.

Note that in FIG. 1, the substrate, one square of which is cut, is shown to indicate the directions of the substrates.

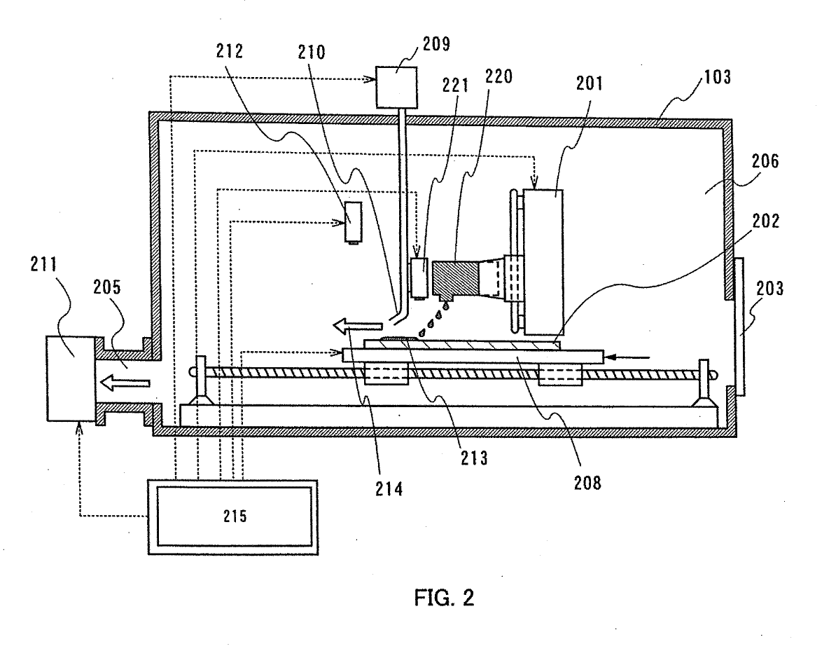

FIG. 2 shows a cross-sectional view of the pattern-forming treatment chamber 103 as one example. Note that in FIG. 2, the same portions as those in FIG. 1 are described with the same reference numerals.

In the pattern-forming treatment chamber 103 shown in FIG. 2, the droplet-discharging means 201, the blowing means 210, a stage (transfer table) 208 for arranging the substrate 202, CCD cameras 212 and 221, an exhaust duct 205 and a substrate transfer door 203 are provided. A gas introduction unit 209, a gas line and a blow nozzle are provided as the blowing means 210, and a gas is discharged from a gas-outlet in the tip of the blow nozzle.

An example of forming a pattern by moving the stage is shown here. Thus, the droplet-discharging means 201, the blowing means 210 and the CCD cameras 212 and 221 are fixed in an X-Y plane. However, the present invention is not limited to this example and the stage may be fixed and the droplet-discharging means 201, the blowing means 210 and the CCD cameras 212 and 221 may be moved in the X-Y plane. If a flexible organic resin material is used for the gas line and the blow nozzle, the gas line and the blow nozzle can be moved.

Here, the CCD camera 221 is unified with the blowing means 210, and the blowing means 210 is separated from the droplet-discharging means 201. However, the CCD camera 221, the blowing means 210 and the droplet-discharging means 201 may be separated from one another, or may be unified and further may be movable without being limited to the structure.

A central processing unit 215 is provided to control the gas introduction unit 209, the CCD cameras 212 and 221, the droplet-discharging means 201, the stage 208 and an exhaust unit 211. When the central processing unit is connected to a production management system or the like with a LAN cable, a wireless LAN, an optic fiber or the like, the process can be collectively controlled from the outside, which leads to enhance productivity.

In addition, as a material which is used for an inner wall of the pattern-forming treatment chamber 103, since it is possible to lessen sorbability of an impurity such as oxygen and water by decreasing its surface area, aluminum, stainless (SUS) or the like which has been changed to a mirror surface by electrolytic polishing, is preferably used for an inside wall. Also, a material such as ceramics, which has been processed so as for air holes to get fewer in the extreme, may be used for an inside member. It is preferable that these are materials having such surface smoothness that center line average asperity becomes 3 nm or less. The pattern-forming treatment chamber 103 preferably has a structure that temperature effect from outside can be suppressed as much as possible so as to control airflow.

The droplet-discharging means 201 is a generic term of a means for discharging a droplet which has a nozzle with a discharging port of a composition, a head 220 equipped with one or a plurality of nozzles or the like. A diameter of a nozzle equipped for the droplet-discharging means is set 0.02 to 100 μm (preferably, 30 μm or less), and the amount of a composition to be discharged from the nozzle is preferably set 0.001 pl to 100 pl (preferably, 0.1 pl or more and 40 pl or less, more preferably 10 pl or less). The amount of discharged droplets is increased in proportion to the diameter of the nozzle. A distance between an object to be treated (such as a substrate) and a discharging port of the nozzle is preferably made as short as possible to drop a droplet on a desired position, which is preferably set about 0.1 to 3 mm (preferably, 1 mm or less).

In this embodiment mode, droplets are discharged by a so-called piezo system using a piezoelectric element; however, a system in which a solution is pushed out by using bubbles generated by heating a heating element, in other words, a thermal ink-jet system, may be used depending on a solution material. In this case, the piezoelectric element is replaced with the heating element. In addition, wettability of a solution with a solution chamber flow path, an extra solution chamber, a fluid resistive portion, a chamber for pressurizing, and a discharging port for a solution (nozzle, head) is important for discharging droplets. Therefore, a carbon film, a resin film or the like for adjusting the wettability with a material is formed in each flow path.

Although not shown, a power source for driving a nozzle and a nozzle heater for discharging droplets are provided in the droplet-discharging means 201, and a movement means for adjusting a position of the droplet-discharging means is also provided. Moreover, a measuring means of various physical properties such as temperature, humidity, flow rate and pressure may be provided as necessary, although not shown.

In such a pattern-forming treatment chamber 103, the substrate 202 is set on the stage 208 provided with the movement means in one direction. A heater may be provided for the stage 208. In this embodiment mode, a position is controlled by the CCD camera 212 when the substrate is moved to a desired position of the X-Y plane by the stage.

In the pattern-forming treatment chamber 103, the gas introduction unit 209 and the exhaust unit 211 are controlled by the central processing unit 215 to keep the direction 214 of airflow (hereinafter, airflow direction 214) constant. The airflow direction 214 is set as the same direction as the movement direction of the stage in a space 206 of the pattern-forming treatment chamber.

In this embodiment mode, droplets are dropped from the droplet-discharging means 201 while keeping the airflow direction 214 constant. By the effect of the airflow direction 214, a flight-trajectory of a droplet becomes an arc. The droplet with an arc-like trajectory that have passed under the CCD camera 221 is imaged by the CCD camera 221. The amount of the droplets is calculated from the droplet image in the central processing unit 215, and the uniform amount of the droplets is obtained by controlling the droplet-discharging means 201 to form a pattern. A wiring pattern 213 is dried or baked by the blowing means.

By the above described structure of the apparatus, the amount of droplets are kept constant while discharging droplets and a pattern can be dried or baked after droplets are landed, in the space 206 of the treatment chamber. Therefore, a fine pattern can be formed over the substrate efficiently and with high accuracy.

There are a sequential method by which a solution is sequentially discharged to form a linear pattern and an on-demand method by which a solution is discharged like a dot as the droplet-discharging method. Both methods can be employed.

### Embodiment Mode 2

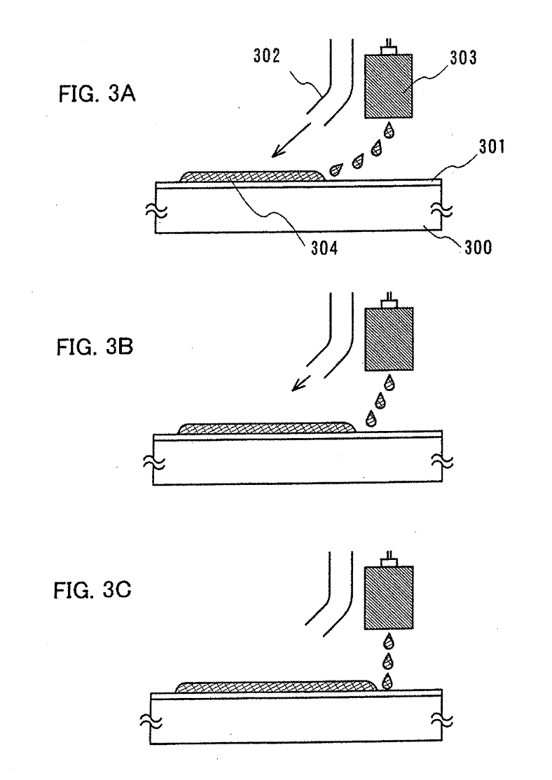

In Embodiment Mode 2, a method for preventing dots from being accumulating at the start point and the end point of a wiring in the case of forming a wiring pattern using a droplet-discharging method is shown with reference to FIGS. 3A to 3C.

In this embodiment mode, an example of preventing dots from being solidified at the end point of a wiring by adjusting a gas flow of a blowing means is shown hereinafter.

First, a base layer 301 is preferably formed entirely or selectively over a substrate 300 (or a base pre-treatment is conducted). Photocatalystic substance (titanium oxide (TiOₓ), strontium titanate (SrTiO₃), cadmium selenide (CdSe), potassium tantalate (KTaO₃), cadmium sulfide (CdS), zirconium oxide (ZrO₂), niobium oxide (Nb₂O₅), zinc oxide (ZnO), ferric oxide (Fe₂O₃), tungsten oxide (WO₃)) may be dropped over the entire surface by a spray method or a sputtering method to form the base layer. Alternatively, a treatment for selectively forming an organic material (polyimide; acrylic; or siloxane) may be carried out by an ink-jet method or a sol-gel method. Siloxane has a skeleton structure with a bond of silicon (Si) and oxygen (O). As a substitute thereof, an organic group including at least hydrogen (such as alkyl group or aromatic hydrocarbon) may be used. Further, a fluoro group may be used for the substitute. Also, an organic group including at least hydrogen and a fluoro group may be used for the substitute.

A treatment for decreasing wettability is conducted to the surface, and then a treatment for selectively enhancing wettability is conducted to the surface whose wettability has been decreased. Thereafter, a wiring or the like may be formed by a dropping method on the surface whose wettability has been enhanced. As the treatment for enhancing wettability, a film containing fluorocarbon resin or a silane coupling agent is selectively formed. A region having a larger contact angle with the composition including the pattern forming material is a region having lower wettability (hereinafter, also referred to as a “low-wettability region”), and a region having a smaller contact angle with the composition including the pattern-forming material is a region having high wettability (hereinafter, also referred to as a “high-wettability region”). This is because when the contact angle is large, a liquid composition having fluidity does not spread and is repelled on the surface of the region; therefore, the surface is not wetted; and when the contact angle is small, a compound having fluidity spreads on the surface, and the surface is wetted. Accordingly, the region having different wettability have different surface energy. The surface of the low wettability region has low surface energy, and the surface of the high wettability region has high surface energy.

A photocatalyst substance refers to a substance having a photocatalyst function that yields photocatalyst activity by being irradiated with light in an ultraviolet region (wavelength of 400 nm or less, preferably, 380 nm or less). If a conductor mixed into solvent is discharged by a droplet-discharging method as typified by an ink-jet method over a photocatalyst substance, a minute drawing can be realized.

Before emitting light to TiO_{X}, TiO_{X} has a lipophilic property but no hydrophilic property, that is, the TiO_{X} has a water-shedding property. By light irradiation, TiO_{X} brings about photocatalyst activity and loses a lipophilic property instead of a hydrophilic property. Further, TiO_{X} is capable of having both of a lipophilic property and a hydrophilic property depending on light irradiation time.

By adding a transition metal (Pd, Pt, Cr, Ni, V, Mn, Fe, Ce, Mo, W, and the like) into a photocatalyst substance, photocatalyst activity can be improved or photocatalyst activity can be yielded due to light in a visible light region (wavelength of 400 to 800 nm). Since light wavelength can be determined by a photocatalyst substance, light irradiation refers to emit light of a wavelength that can yield photocatalyst activity of the photocatalyst substance.

In FIG. 3A, a pattern 304 is being formed by relatively moving a stage on which the substrate 300 is set or a droplet-discharging means 303, and the flight-trajectory of droplets is an arc by the blowing means 302 before landing on the substrate.

FIG. 3B shows a mode in which the stage on which the substrate 300 is set and the droplet-discharging means 303 are fixed, and the gas flow from the blowing means is more reduced than that in FIG. 3A and the flight-trajectory of droplets is changed.

FIG. 3C shows a mode in which the stage on which the substrate 300 is set and the droplet-discharging means 303 are fixed, and the gas flow from the blowing means is zero and thus droplets are dropped under the nozzle due to free-fall.

In this manner, in the vicinity of the end point of the wiring, the gas flow from the blowing means is reduced gradually. Thus, a pattern can be formed with the stage and the droplet-discharging means fixed. In addition, discharging droplets is stopped when the gas flow from the blowing means becomes zero, a block of dots can be prevented from being formed (in other words, droplets are prevented from being accumulated) at the end point of the wiring.

Further, at the start point of the wiring, a pattern can be formed with the stage and the droplet-discharging means fixed by gradually increasing the gas flow from the blowing means. A block of dots can be prevented from being formed at the start point of the wiring by gradually increasing the gas flow.

At the start point of the wiring, the gas flow is decreased while discharging droplets and when the gas flow from the blowing means becomes zero, a pattern may be formed by moving the stage or the droplet-discharging means while discharging droplets. In this case, the pattern is formed with keeping the gas flow from the blowing means zero, except at the start or end point of the wiring.

This embodiment mode can be freely combined with Embodiment Mode 1.

### Embodiment Mode 3

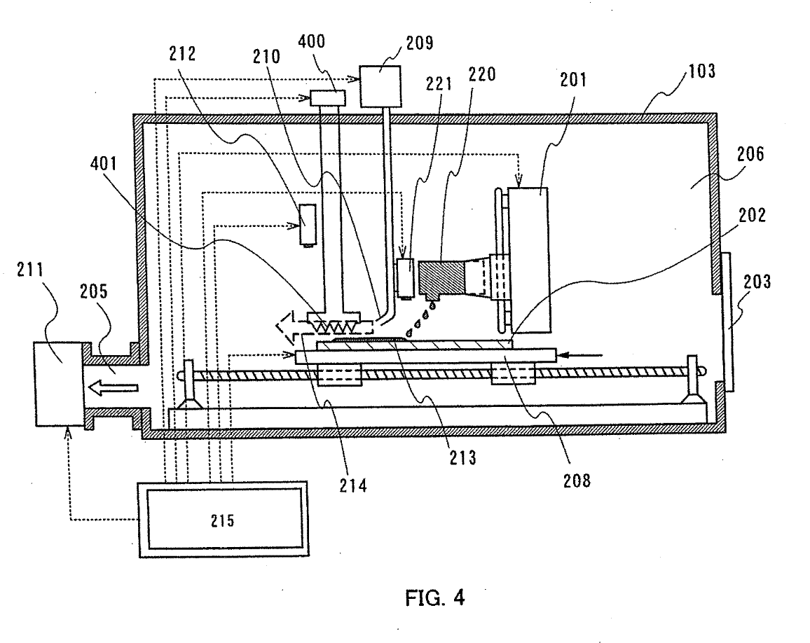

Embodiment Mode 3 shows an example of providing a heating means (heater) in addition to the structure shown in FIG. 2 of Embodiment Mode 1 in a pattern-forming treatment chamber 103. Note that the same portions as those in FIG. 2 are described with the same reference numerals in FIG. 4. The detailed description of the same portions as those in FIG. 2 is omitted for simplification.

If a gas heated at a high temperature is blown by a blowing means, there is a risk that a droplet-discharging means 201 is influenced thereby and discharging becomes unstable. If a flexible organic resin material is used for a gas line and a blow nozzle, it becomes difficult to blow the gas heated at a high temperature. A heating means is arranged keeping an interval between it and the droplet-discharging means downstream of airflow formed by the blowing means.

As the heating means, a heat-generating power source unit 400 and a resistant heating element 401 such as lead wire or nichrome wire are used. The heat-generating power source unit 400 is also preferably controlled by a central processing unit 215. Note that the resistant heating element 401 may be string-like, wire-like, coil-like, stick-like or planar. A ceramic material such as silicon carbide (SiC), chromic acid lantern (LaCrO₃), or dioxide zircon (ZrO₂) or these ceramic materials mixed with metallic powders may be employed as the resistant heating element 401.

The heating means is not limited to the resistant heating element and may be a thermoelectric conversion element using Seebeck effect or Thomson effect

A wiring pattern 213 is dried or baked by heating the gas blown from the blowing means by the heating means. A temporary baking is conducted for a certain time after the droplets are landed, thereby obtaining a uniform pattern, even if difference in time during exposure to the air between a portion where a pattern is formed first and a portion where a pattern is formed last, becomes larger. Since the heater (heating means) is provided in a gas flow path, rapid-heating for a pattern of a landed material can be prevented. Further, the total baking time can be shortened by heating in the treatment chamber after discharging.

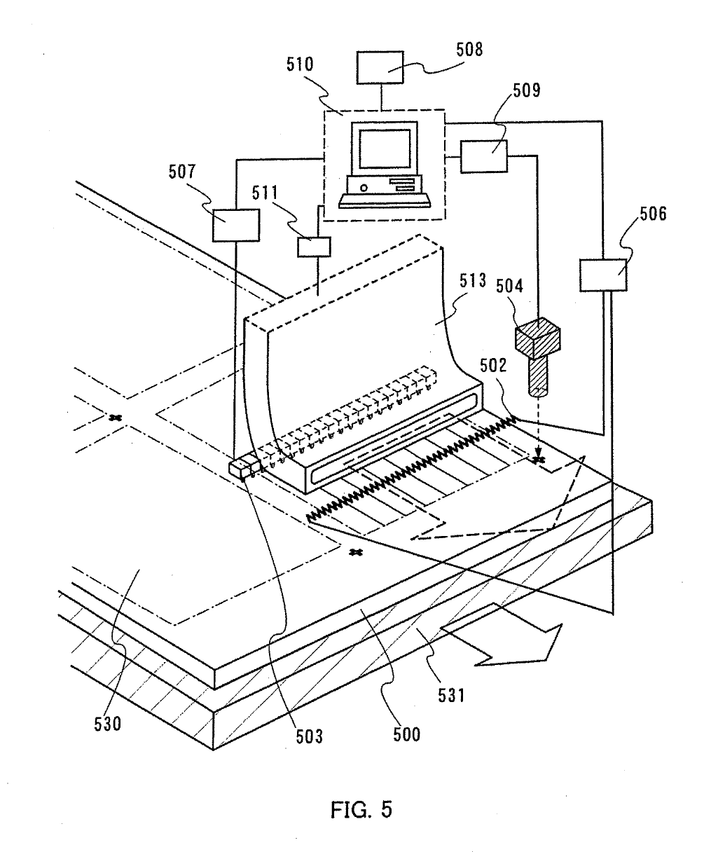

FIG. 5 shows a perspective view of an apparatus system that can form a pattern on a large substrate as one example.

In FIG. 5, a region for forming one panel 530 on a large substrate 500 is shown by the dotted line.

FIG. 5 shows one mode of a droplet-discharging apparatus to be used for forming a pattern of a wiring or the like. The droplet-discharging means has a head that has a plurality of nozzles 503. This embodiment mode shows a case of using one head provided with the plurality of nozzles; however, the number of nozzles or heads can be set depending on an area to be processed, process or the like.

It is preferable that the width of the head is substantially equal to that of one panel, when a plurality of panels are formed from one large mother glass. A pattern can be formed in the region for forming one panel 530 by one-time scanning, and thus higher throughput can be expected.

The head is connected to a discharge-controlling means 507, and the droplet-discharging means is controlled by a computer 510, thereby drawing a pattern that has been designed. The timing for drawing may be determined by using, for example, a marker formed on the substrate 500 or the like that is fixed on the stage 531 as a reference point. Alternatively, the patterning may be carried out from the edge of the substrate 500 as the reference point. The reference point is detected with an imaging means 504 such as a CCD, and the detected information is converted into a digital signal by an image processing means 509. The converted digital signal is recognized by the computer 510, and a control signal is generated and transmitted to the discharge-controlling means 507. When a pattern is thus drawn, the distance between the end of the nozzles and the surface where a pattern is to be formed may be 0.1 cm to 5 cm, preferably 0.1 cm to 2 cm, more preferably around 0.1 mm. As thus the distance is reduced, the landing-accuracy of droplets is improved.

Hereupon, the information of the pattern to be formed over the substrate 500 is stored in a storage medium 508. A control signal is sent to a discharge-controlling means 507 based on the information; thus, each nozzle can be controlled individually.

A blowing means 513 is provided and a gas is blown to the substrate, thereby forming airflow in the direction shown by the dotted line. The direction of the airflow is preferably the same as the movement direction of the stage. The blowing means 513 is connected to a blow-controlling means 511, and the blow-controlling means is controlled by the computer 510.

By providing a heating means (heater) 502, a blown gas is heated to dry a pattern. The heating means 502 is connected to a heating-controlling means 506, and the heating-controlling means is controlled by the computer 510.

A cooling means may be provided instead of the heating means 502. The wiring pattern can be cooled by the cooling means and the blowing means, thereby preventing the wiring pattern from being dried. A thermoelectric conversion element using Peltier effect may be used as the cooling means. Further, the cooling means is provided in a gas flow path, and thus rapid cooling to a pattern of the landed material can be prevented.

This embodiment mode can be freely combined with Embodiment Mode 1 or Embodiment Mode 2.

### Embodiment Mode 4

Embodiment Mode 4 describes a method for manufacturing a thin film transistor as one example.

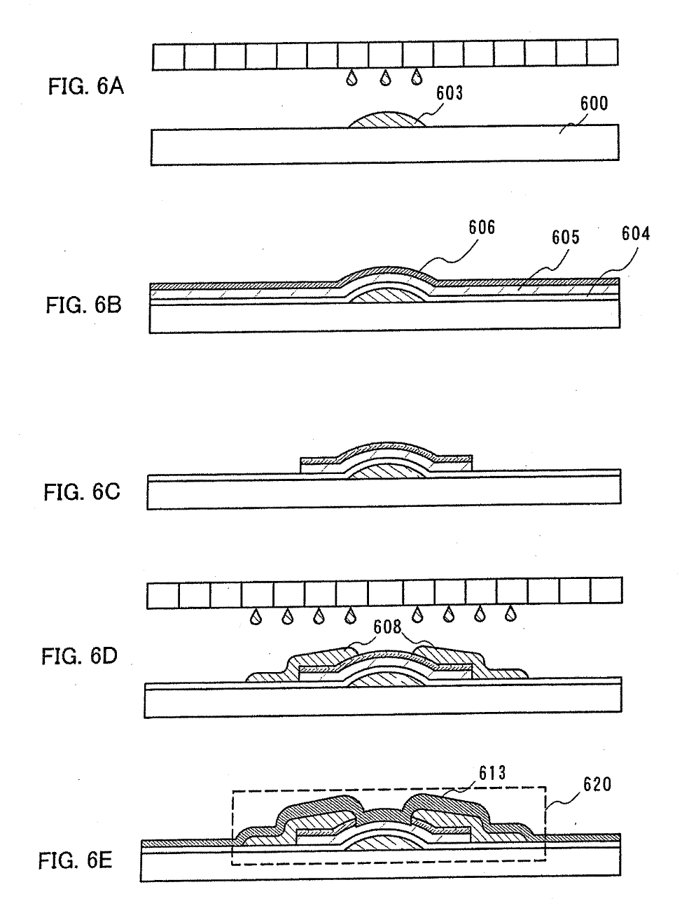

First, as shown in FIG. 6A, a substrate 600 having an insulating surface is prepared. For example, a glass substrate such as barium borosilicate glass or alumino borosilicate glass; a quartz substrate; a stainless substrate; or the like can be used as the substrate 600. Further, a substrate formed of a flexible synthetic resin such as acrylic or plastics typified by polyethylene-terephthalate (PET), polyethylene naphthalate (PEN), and polyethersulfone (PES) generally has low heat-resistant temperature as compared with a substrate formed of another material. However, such substrates can be used as long as it can endure a processing temperature of the manufacturing process. In particular, in the case of forming a thin film transistor including an amorphous semiconductor film which does not require a heating step of crystallizing a semiconductor film, the substrate made of a synthetic resin can readily be used.

A base film is formed over the substrate 600 as necessary. The base film is formed in order to prevent an alkaline metal such as Na or an alkaline earth metal contained in the substrate 600 from spreading in a semiconductor film and exerting an adverse effect on semiconductor element characteristics and in order to enhance the planarity. The base film can be therefore formed using an insulating film such as silicon oxide, silicon nitride, silicon nitride oxide, titanium oxide, or titanium nitride, which is capable of suppressing the spread of an alkaline metal or an alkaline earth metal into the semiconductor film. The base film can be formed by using a conductive film of titanium or the like. In this case, the conductive film may be oxidized by a heat treatment or the like in a manufacturing process. Specifically, a material of the base film may be selected from materials having high adhesion with a gate electrode material. For example, a base film of titanium oxide (TiOx) is preferably formed when Ag is used for the gate electrode. Note that the base film may have a single layer structure or a laminated structure.

The base film is not necessarily provided, as long as it is possible to prevent impurities from diffusing into the semiconductor film. As in this embodiment mode, when a semiconductor film is formed over a gate electrode with a gate insulating film therebetween, the base film is not needed since the gate insulating film can prevent impurities from diffusing into the semiconductor film.

Moreover, in some cases, it is preferable to provide a base film depending on a material of the substrate. It is effective to provide a base film in order to prevent impurities from spreading in the case of using a substrate which contains somewhat alkaline metal or an alkaline earth metal, such as a glass substrate, a stainless substrate or a plastic substrate. Meanwhile, a base film is not required to be provided necessarily when using a quartz substrate or the like, in which impurity spread does not cause much trouble.

Then, by using a manufacturing apparatus using an ink-jet method shown in FIGS. 1 and 2, dots mixed with a conductor in a solvent are dropped and a gas is blown by the blowing means to form a conductive pattern serving as a gate electrode 603 and a gate wiring (FIG. 6A). In this embodiment mode, patterns in an X direction and a Y direction are formed in different pattern-forming treatment chambers respectively to enhance productivity. The gate electrode that branches from the gate wiring is formed in a different pattern-forming treatment chamber to be unified (integrated). In this embodiment mode, dots in which a conductor of silver (Ag) are dispersed in a solvent of tetradecane is dropped.

When the solvent of the dots are required to be removed, a heat treatment is carried out for baking or drying at a predetermined temperature, specifically at a temperature of 200° C. to 300° C. It is preferable to carry out a heat treatment in an oxygen containing atmosphere. In this case, the heating temperature is set so as not to generate roughness on the surface of the gate electrode. When dots containing silver (Ag) are used as in this embodiment mode, a heat treatment is preferably carried out in an atmosphere containing oxygen and nitrogen. Correspondingly, an organic material such as a thermosetting resin of an adhesive agent or the like contained in the solvent is decomposed; thus, silver (Ag) which does not contain an organic material can be obtained. Consequently, planarity of the gate electrode surface can be improved and specific resistance value can be lowered.

In this embodiment mode, the time needed for a heat treatment to be conducted later can be shortened, since the gas is blown by the blowing means.

Then, an insulating film which serves as a gate insulating film 604 is formed to cover the gate electrode. The insulating film can have a laminated structure or a single layer structure. An insulator such as silicon oxide, silicon nitride or silicon nitride oxide can be formed as the insulating film by a plasma CVD method. Note that dots including a material of an insulating film may be discharged by an ink-jet method to form the gate insulating film. As in this embodiment mode, when the gate electrode contains silver (Ag), it is preferable that a silicon nitride film is used for the insulating film covering the gate electrode. This is because there is a risk that a surface of the gate electrode becomes rough, since silver oxide is formed by a reaction with silver (Ag), in the case of using an insulating film including oxygen.

A semiconductor film 605 is formed over the gate insulating film. The semiconductor film can be formed by a plasma CVD method, a sputtering method, an ink-jet method or the like. The semiconductor film is 25 to 200 nm thick (preferably, 30 to 60 nm). Silicon germanium as well as silicon can be used for the material of the semiconductor film. In the case of using silicon germanium, the concentration of germanium is preferably about 0.01 to 4.5 atomic %. In addition, the semiconductor film may be an amorphous semiconductor, a semi-amorphous semiconductor in which crystal grains are dispersed in an amorphous semiconductor or a micro crystal semiconductor in which crystal grains of 0.5 nm to 20 nm can be seen in an amorphous semiconductor. Note that a state of a micro crystal in which crystal grains of 0.5 nm to 20 nm can be seen is referred to as a micro crystal (μc).

Semi-amorphous silicon using silicon (also referred to as SAS) as a material of a semi-amorphous semiconductor can be obtained by grow discharge decomposition of a silicide gas. As a typical silicide gas, SiH₄ is cited, besides, Si₂H₆, SiH₂Cl₂, SiHCl₃, SiCl₄, SiF₄ and the like can be used. SAS can be formed easily by a silicide gas diluted with hydrogen, or hydrogen and one or more rare gas elements selected from helium, argon, krypton, and neon. The silicide gas is preferably diluted so that the dilution rate is in the range of 10 times to 1000 times. SAS can be also formed with Si₂H₆ and GeF₄ by a method of diluting it with a helium gas. The reactive formation of a film by grow discharge decomposition is preferably conducted under low pressure, and the pressure may be about 0.1 Pa to 133 Pa. The power for grow discharge may be 1 MHz to 120 MHz, preferably, a high frequency power of 13 MHz to 60 MHz. The substrate heating temperature is preferably 300° C. or less, and more preferably, substrate heating temperature of 100° C. to 250° C. is recommended.

In this embodiment mode, an amorphous semiconductor film (also, referred to as an amorphous silicon film or amorphous silicon) containing silicon as the main component is formed by a plasma CVD method.

A semiconductor film having one conductivity type is formed. The semiconductor film having one conductivity type can be formed by a plasma CVD method, a sputtering method, an ink-jet method or the like. When the semiconductor film having one conductivity type is formed, contact resistance of a semiconductor film and an electrode becomes low, which is preferable. However, the semiconductor film having one conductivity type may be formed as necessary. In this embodiment mode, a semiconductor film having N type conductivity 606 is formed by a plasma CVD method (FIG. 6B). When the semiconductor film and the semiconductor film having N type conductivity are formed by using a plasma CVD method, the semiconductor film 605, the semiconductor film having N type conductivity 606, and a gate insulating film are preferably formed sequentially. The sequential formation is possible by varying a material gas supply without being exposed to the air.

As shown in FIG. 6C, the semiconductor film 605 and the semiconductor film having N type conductivity 606 are patterned into a desired shape. Although not shown, a mask may be formed in a desired portion and the films may be etched by using the mask. The mask is preferably formed by an ink-jet method, because efficiency in the use of a material can be improved, and a cost and an amount of waste liquid can be reduced. Alternatively, the mask may be formed by a photolithography method. When the mask is formed by an ink-jet method, further, a photolithography process can be simplified. In other words, a step of forming a photomask, a light-exposure step and the like are not required, and therefore, a facility investment cost can be reduced and manufacturing time can be shortened.

As the mask material, an inorganic material (such as silicon oxide, silicon nitride, silicon oxynitride), a photosensitive or non-photosensitive organic material (such as polyimide, acrylic, polyamide, polyimidamide, polyvinyl alcohol, benzocyclobutene or resist) can be used. For example, when a mask is formed from polyimide by an ink-jet method, polyimide may be discharged at a desired portion by an ink-jet method and then may be heated at 150° C. to 300° C. to be baked.

A conductive film functioning as a source electrode and a drain electrode 608 is formed. The conductive film may have a single layer structure or a laminated structure. As the conductive film, a film made of an element selected from gold, silver, copper, aluminum, titanium, molybdenum, tungsten or silicon or an alloy film using the element, can be used. Further, the conductive film can be formed by an ink-jet method, a CVD method or a sputtering method.

In this embodiment mode, the source and drain electrodes 608 are formed by using dots including silver (Ag) by an ink jet method (FIG. 6D). Specifically, it is performed in the same manner as the gate electrode. Since dots are dropped in a region treated by a plasma treatment, the source and drain electrodes formed by an ink jet method can be miniaturized.

After that, the semiconductor film having N type conductivity is selectively etched using the source and drain electrodes 608 as a mask. This is because the semiconductor film having N type conductivity prevents the source and drain electrodes from being short-circuited. At this time, an upper portion of the semiconductor film 605 can be also etched to some extent in some cases.

Then, a protective film 613 containing an inorganic insulating film is formed (FIG. 6E). The protective film 613 is formed using an insulating film such as silicon oxide, silicon nitride, or silicon nitride oxide by an ink-jet method, a plasma CVD method, a sputtering method or the like.

As described above, a thin film transistor 620 in which up to the source and drain electrodes have been provided is formed. The thin film transistor in this embodiment mode is a so-called bottom gate type thin film transistor, in which the gate electrode is formed under the semiconductor film. More in detail, it is a so-called channel etch type, in which the semiconductor film is etched to some extent. A substrate where such plural thin film transistors are formed is referred to as a TFT substrate.

Efficiency in the use of materials improves, and a cost and an amount of waste liquid can be reduced when a wiring, a mask or the like is formed by an ink-jet method. In particular, the process in the case of forming a mask by an ink-jet method are more simplified than when using a photolithography process. Consequently, reduction of costs such as a facility investment cost can be achieved, and manufacturing time can be shortened.

This embodiment mode can be freely combined with Embodiment Modes 1 to 3.

### Embodiment Mode 5

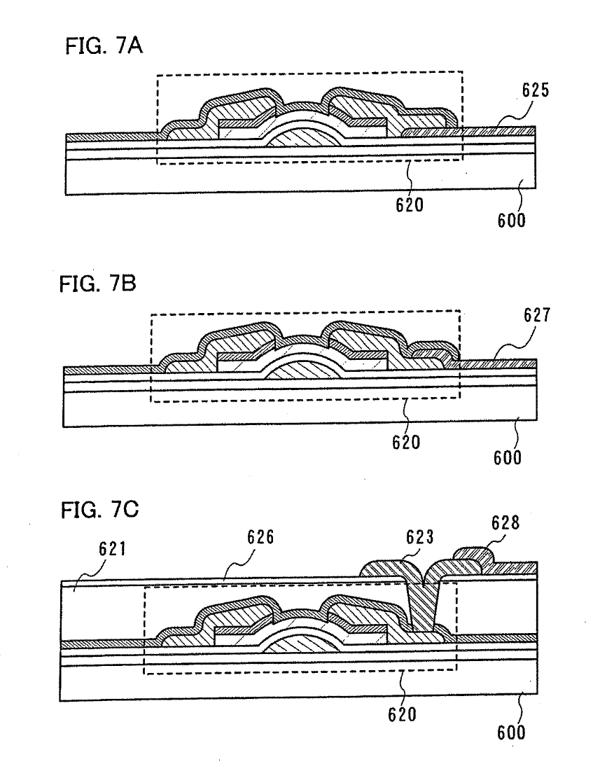

Embodiment Mode 5 describes a method for forming a pixel electrode connected to a thin film transistor. Note that the same portions as those in FIGS. 6A to 6E are described with the same reference numerals in FIGS. 7A to 7C.

As shown in FIG. 7A, a thin film transistor (TFT) 620 having a protective film 613 is formed over a substrate 600 having an insulating surface according to Embodiment Mode 4. In this embodiment mode, a TFT described in Embodiment Mode 4 is shown; however, another TFT structure may be employed. In addition, an electrode to become a pixel electrode 625 is formed below the electrode so as to be connected to the source electrode or the drain electrode.

After forming a gate insulating film, a semiconductor film and a semiconductor film having N type conductivity are patterned to form the pixel electrode in the area for forming the source electrode or the drain electrode. The pixel electrode can be formed by a sputtering method or an ink jet method. The pixel electrode is formed using a light-transmitting material or a non-light transmitting material. For example, ITO and the like can be used as a light-transmitting material, whereas a metal film can be used as a non-light transmitting material. ITO (indium tin oxide), IZO (indium zinc oxide) in which zinc oxide (ZnO) of 2% to 20% is mixed into indium oxide, ITO—SiOx in which silicon oxide (Si0₂) of 2% to 20% is mixed into indium oxide (referred to as ITSO for convenience), organic indium, organotin, titanium nitride (TiN), and the like can also be used as specific examples of the pixel electrode.

In FIG. 7A, dots dispersed with a conductor of ITO are dropped by an ink-jet method to form an electrode to become a pixel electrode 625. After that, a heat treatment for baking or drying is conducted when the solvent of the dots is required to remove.

FIG. 7B shows an example of forming a pixel electrode over the source electrode or the drain electrode, which is different from that of FIG. 7A. The pixel electrode 627 can be formed by a sputtering method or an ink jet method, as described above.

In FIG. 7C, an interlayer insulating film 621 is formed and planarized, and then, a wiring 623 is formed and connected to a pixel electrode 628, which is different from in FIGS. 7A and 7B.

As the interlayer insulating film 621, an inorganic material (such as silicon oxide, silicon nitride, silicon oxynitride), a photosensitive or non-photosensitive organic material (such as polyimide, acrylic, polyamide, polyimidamide, benzocyclobutene or resist), siloxane, polysilazane and a laminated structure thereof can be used. As the organic material, positive type photosensitive organic resin or negative photosensitive organic resin can be used. In particular, siloxane may be used as the interlayer insulating film 621. Further, an insulating film containing nitrogen, e.g. silicon nitride or silicon oxynitride may be formed on the interlayer insulating film of siloxane. When a light-emitting element having such a structure is formed, light-emitting intensity and a lifetime can be improved. When acrylic or polyimide is used for the interlayer insulating film 621, the insulating film containing nitrogen 626 can be eliminated. In such a structure, a liquid element may be formed.

The wiring 623 and the pixel electrode 628 can be formed by a sputtering method or an ink-jet method as described above.

In FIG. 7C, ITSO is employed as the pixel electrode 628. The ITSO can be formed by dropping dots dispersed with a conductor of ITO and silicon by an ink-jet method. Alternatively, the ITO can be formed by a sputtering method using an ITO containing silicon as a target.

A TFT substrate in which up to the pixel electrode has been formed is referred to as a module TFT substrate.

This embodiment Mode can be freely combined with Embodiment Modes 1 to 4.

### Embodiment Mode 6

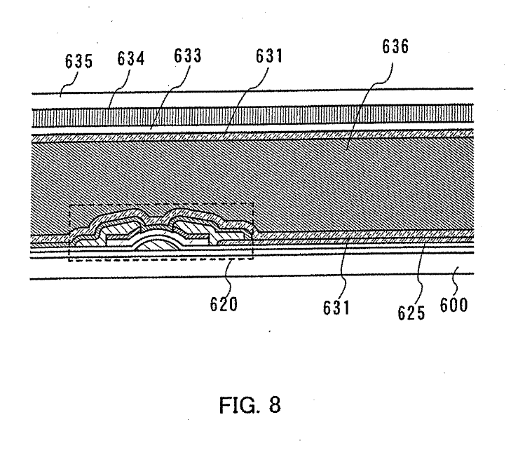

In Embodiment Mode 6, a display device including a liquid crystal module having a thin film transistor (a liquid crystal display device) shown in Embodiment Mode 4 or 5 is described with reference to FIG. 8. Note that the same portions as those in FIG. 6 or 7 are described with the same reference numerals in FIG. 8.

FIG. 8 is a cross-sectional view of a liquid crystal display device having a thin film transistor 620 and an electrode to become a pixel electrode 625 formed over a TFT substrate as described in Embodiment Mode 5. When a light-transmitting conductive film (such as ITO or ITSO) is used for the electrode to become a pixel electrode 625, a transmissive liquid crystal display device can be obtained. On the contrary, when a non light-transmitting film, that is, a high-reflective film (e.g., aluminum) is used, a reflective liquid crystal display device can be obtained. A module TFT substrate used for a liquid crystal display device like this embodiment mode is referred to as a liquid crystal module TFT substrate.

An orientation film 631 is formed to cover the thin film transistor 620, a protective film, and the electrode to become a pixel electrode 625.

After that, the substrate 600 is attached to an opposite substrate 635 by a sealing material and a liquid crystal is injected thereinto to form a liquid crystal layer 636, thereby obtaining a liquid crystal module.

A color filter 634, an opposite electrode 633, and the orientation film 631 are formed sequentially over the opposite substrate 635. The color filter, the opposite electrode or the orientation film can be formed by an ink jet method. Although not shown, a black matrix may be also formed by an ink-jet method.

When the liquid crystal is injected, a treatment chamber that is to be in a vacuum state is required. Note that the liquid crystal may be dropped and an ink-jet method may be employed for the dropping method of the liquid crystal. In particular, in the case of a large substrate, the liquid crystal is preferably dropped. This is because a larger treatment chamber is required, a substrate weighs more and a treatment is more difficult, as the substrate becomes larger, in the case of a liquid crystal injection method.

When the liquid crystal is dropped, a sealing material is formed in the periphery of one substrate of the two substrates. The reason why one substrate is described is that the sealing material may be formed in either the substrate 600 or the opposite substrate 635. At this time, the sealing material is formed in the closed area where the end point is accorded with the initial point of the sealing material. After that, one drop or more drops of liquid crystals is/are dropped. In the case of a large substrate, plural drops of liquid crystals are dropped in plural portions. Then, the substrate is attached to the other substrate in vacuum. This is because it is possible to remove unnecessary air and to prevent the sealing material from being broken and expanded due to air, by making the vacuum state.

Then, two or more points in the region where the sealing material is formed are solidified and bonded for temporary attachment. Two or more points in the region where the sealing material is formed may be irradiated with ultraviolet rays, when ultraviolet curable resin is used for the sealing material. After that, the substrate is taken out of the treatment chamber, and the whole sealing material is solidified and bonded for complete attachment. At the time, a light-shielding material is preferably arranged so that a thin film transistor or a liquid crystal may not be irradiated with ultraviolet rays.

A pillar like or spherical spacer may be used in addition to the sealing material so as to keep the gap between the substrates.

In this manner, the liquid crystal module shown in FIG. 8 is completed.

After that, an external terminal may be connected to a signal line driver circuit or a scanning line driver circuit by bonding an FPC (Flexible Printed Circuit) using anisotropic conductive film. Further, the signal line driver circuit or the scanning line driver circuit may be formed as an external circuit.

At this stage, a liquid crystal display device in which the thin film transistor having a wiring formed by a droplet-discharging method is provided and to which the external terminal is connected, can be formed.

This embodiment mode can be freely combined with Embodiment Modes 1 to 5.

An interlayer insulating film may be formed to increase planarity by using a structure shown in FIG. 7C of Embodiment Mode 5, although the structure shown in FIG. 7A of Embodiment Mode 5 is described in this embodiment mode. When the planarity is increased, an orientation film can be formed uniformly and voltage can be applied to a liquid crystal layer uniformly, which is preferable.

### Embodiment Mode 7

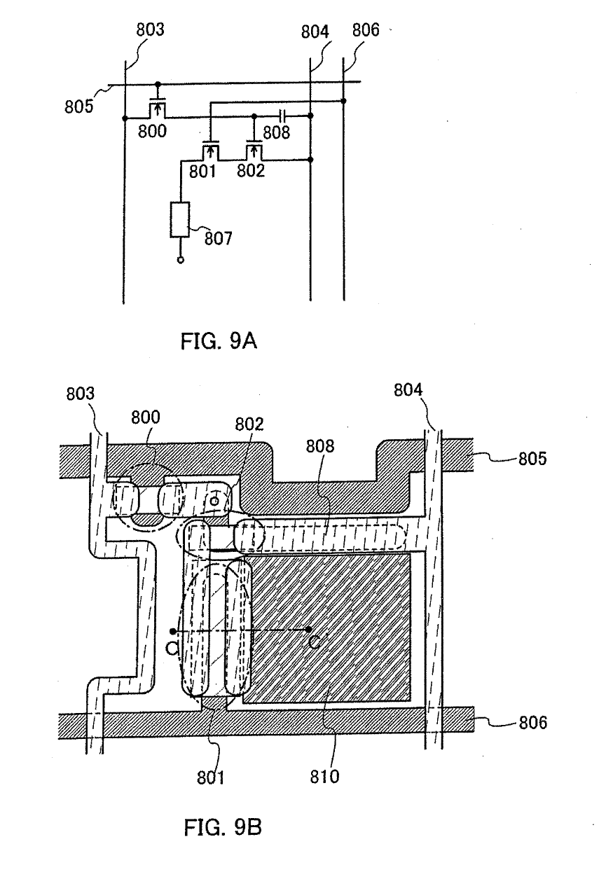

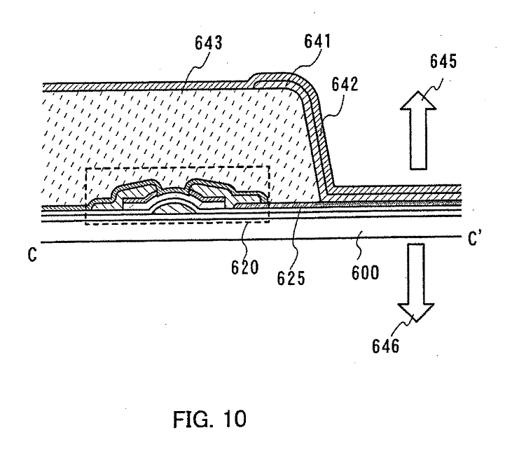

A display device including a light-emitting module having a thin film transistor shown in Embodiment Mode 4 or 5 (light-emitting device) is described with reference to FIGS. 9A, 9B and 10. Note that the same portions as thoze in FIG. 6 or 7 are described with the same reference numerals in FIG. 10.

FIG. 10 is a cross-sectional view of a light emitting device having a thin film transistor 620 and an electrode to become a first electrode (e.g., pixel electrode) 625 formed in the TFT substrate shown in Embodiment Mode 5. The thin film transistor 620 having the electrode to become a first electrode 625 is formed according Embodiment Mode 5. The electrode to become a first electrode 625 functions as a first electrode of a light-emitting element.

After that, an insulating film 643 functioning as a bank or a barrier is selectively formed. The insulating film 643 is formed to cover the periphery portion of the electrode to become a first electrode 625, thereby filling a space of pixel electrodes. As the insulating film 643, an inorganic material (such as silicon oxide, silicon nitride, silicon oxynitride), a photosensitive or non-photosensitive organic material (such as polyimide, acrylic, polyimide, polyimidamide, benzocyclobutene or resist), siloxane, polysilazane and a laminated structure thereof can be used. As the organic material, positive photosensitive organic resin or negative photosensitive organic resin can be used. For example, in the case of using positive photosensitive acrylic as the organic material, the photosensitive organic resin is etched by light-exposure to form an opening portion with a curvature in the upper edge portion. This can prevent an electroluminescent layer to be formed later or the like from being disconnected. The TFT substrate in this state is referred to as a light emitting module TFT substrate.

An electroluminescent layer 641 is formed in the opening portion of the insulating film 643 formed over the first electrode. A vacuum-heating treatment may be performed before forming the electroluminescent layer. In this embodiment mode, the vacuum-heating treatment is conducted and the electroluminescent layer containing a high-molecular weight compound is formed in the opening portion of the insulating film 643 by an ink-jet method.

Thereafter, a second electrode 642 of the light-emitting element is formed to cover the electroluminescent layer 641 and the insulating film 643.

A singlet excited state and a triplet excited state are possible as a kind of the molecular exciton formed by the electroluminescent layer 643. A ground state is generally a singlet excited state, and light emission from a singlet excited state is referred to as fluorescence. Light emission from a triplet excited state is referred to as phosphorescence. Light-emission from an electroluminescent layer includes light emission generated by the both excited states. Further, fluorescence and phosphorescence may be combined, and either of them can be selected depending on luminescence property (such as light-emitting intensity or a lifetime) of respective RGB.

The electroluminescent layer 641 is formed by laminating in order HIL (hole injecting layer), HTL (hole transporting layer), EML (light emitting layer), ETL (electron transporting layer), EIL (electron injecting layer) sequentially from the first electrode side, in other words, the side of the electrode to become a first electrode 625. Note that the electroluminescent layer can employ a single layer structure or a combined structure other than a laminated structure.

Materials for light emission of red (R) green (G) and blue (B) are each selectively formed by a vapor deposition method using a vapor-deposition mask or the like as the electroluminescent layer 641. The materials for light emission of red (R) green (G) and blue (B) can be formed also by an ink-jet method, and this method is preferable since it is possible to individually apply each RGB without using a mask.

Specifically, CuPc or PEDOT for HIL, α-NPD for HTL, BCP or Alg₃ for ETL and BCP: Li or CaF₂ for EIL are used respectively. Alq₃ doped with a dopant corresponding to each light emission of RGB (DCM or the like for R, DMQD or the like for G) may be used for EML, for example.

Note that the electroluminescent layer 641 is not limited to the above material. For example, the hole injection property can be enhanced by co-evaporating oxide such as molybdenum oxide (MoOx: x=2 to 3) and α-NPD or rubrene to form a film instead of using CuPc or PEDOT. An organic material (including a low molecular weight material or a high molecular weight material) or a composite material of an organic material and an inorganic material can be used as the material of the electroluminescent layer.

The case of forming materials for light emission of each RGB is described above, but a material for monochrome light emission is formed and a color filter or a color conversion layer is combined to display with full color. For example, when an electroluminescent layer for light emission of white or orange is formed, a color filter, or a color filter combined with a color conversion layer is provided separately to obtain a full color display. A color filter or a color conversion layer may be formed on a second substrate (sealing substrate), for example, and attached to a substrate. A material for monochrome light emission, a color filter, and a color conversion layer can be each formed by an ink-jet method.

A display of monochrome light emission may be performed. For example, an area color type display device may be formed by using monochrome light emission to mainly display characters and symbols.

In addition, it is necessary to select materials of the electrode to become a first electrode 625 and the second electrode 642 in consideration of the work function. However, the first electrode and the second electrode can be an anode or a cathode depending on a pixel structure. It is preferable that the first electrode is a cathode and the second electrode is an anode in this embodiment mode, since the polarity of a driving TFT is an N channel type. On the contrary, it is preferable that the first electrode is an anode and the second electrode is a cathode when the polarity of the driving TFT is a P channel type.

Hereinafter, electrode materials used for the anode and the cathode are described.

It is preferable to use a metal, an alloy, an electric-conductive compound, a mixture thereof, or the like having a high work function (work function: 4.0 eV or more) as the electrode material used for the anode. ITO (indium tin oxide), IZO (indium zinc oxide) in which zinc oxide (ZnO) of from 2% to 20% is mixed into indium oxide, ITSO in which silicon oxide (SiO₂) of from 2% to 20% is mixed into indium oxide, gold, platinum, nickel, tungsten, chromium, molybdenum, iron, cobalt, copper, palladium, a nitride of a metal material (such as titanium nitride) and the like can be cited as specific materials.

On the other hand, it is preferable to use a metal, an alloy, an electric-conductive compound, a mixture thereof, or the like having a low work function (work function: 3.8 eV or less) as the electrode material used for the cathode. An element belonging to Group 1 or 2 in the periodic table, that is, an alkaline metal such as lithium or cesium, an alkaline earth metal such as magnesium, calcium, or strontium, an alloy (Mg:Ag or Al:Li) or a compound (LiF, CsF, or CaF₂) including them, or a transition metal including a rare-earth metal can be cited as specific materials.

The first electrode and the second electrode can be formed by a vapor deposition method, a sputtering method, an ink jet method, or the like.

In the case of forming a conductive film, ITO or ITSO, or a laminated body thereof as the second electrode by a sputtering method, the electroluminescent layer may be damaged from the sputtering. In order to reduce damages from the sputtering method, oxide such as molybdenum oxide (MoOx: x=2 to 3) is preferably formed on a top surface of the electroluminescent layer. Therefore, the oxide such as molybdenum oxide (MoOx: x=2 to 3) which functions as HIL or the like is formed on a top face of the electroluminescent layer. EIL (electron injecting layer), ETL (electron transporting layer), EML (light emitting layer), HTL (hole transporting layer), HIL (hole injecting layer), and the second electrode may be laminated in this order from the side of the first electrode, At this time, the first electrode functions as a cathode and the second electrode functions as an anode.

Since the polarity of the driving TFT is an N channel type in this embodiment mode, it is preferable to employ a structure of the first electrode that is a cathode, EIL (electron injecting layer), ETL (electron transporting layer), EML (light emitting layer), HTL (hole transporting layer), HTL (hole injecting layer), and the second electrode that is an anode in consideration of the moving direction of electrons.

Thereafter, a passivation film containing nitrogen, a DLC (Diamond like carbon) or the like may be formed to cover the second electrode by a sputtering method or a CVD method. Accordingly, penetration of moisture and oxygen can be prevented. In addition, penetration of oxygen and moisture can be prevented by covering the side face of the display device with the first electrode, the second electrode, or another electrode. Subsequently, a sealing substrate is attached. A space formed by the sealing substrate may be encapsulated with an inert gas or may be provided with a desiccant agent. In addition, light transmitting and highly water-absorbing resin may be filled therein.

The light emitting module shown in FIG. 10 is completed in this manner.

In the light emitting module, when the first electrode and the second electrode are formed to transmit light, light is emitted from the electroluminescent layer in the directions shown by both arrows 645 and 646, with a brightness corresponding to a video signal inputted from a single line. When the first electrode is light-transmitting and the second electrode is not light-transmitting, light is emitted only in the direction of the arrow 646. When the first electrode is not light-transmitting and the second electrode is light-transmitting, light is emitted only in the direction of the arrow 645. At the time, light can be efficiently utilized by using a highly reflective conductive film as the non-light-transmitting electrode provided on a side which is not a light emitting direction.

After that, an external terminal may be connected to a signal line driver circuit or a scanning line driver circuit by bonding an FPC (flexible printed circuit) using anisotropic conductive film. Further, the signal line driver circuit or the scanning line driver circuit may be formed as an external circuit.

Like this, a light-emitting display device in which a thin film transistor having a wiring formed by a droplet-discharging method and to which the external terminal is connected, can be formed.

FIG. 9A illustrates an equivalent circuit diagram of a pixel portion of the light emitting device. One pixel includes a TFT for switching (switching TFT) 800, a TFT for driving (driving TFT) 801, and a TFT for controlling current (current controlling TFT) 802. Theses TFTs are N channel types. One electrode and a gate electrode of the switching TFT 800 are connected to a signal line 803 and a scanning line 805, respectively. One electrode of the current controlling TFT 802 is connected to a first power supply line 804, and a gate electrode thereof is connected to the other electrode of the switching TFT.

A capacitor element 808 may be provided to hold gate-source voltage of the current controlling TFT. In this embodiment mode, when electric potential of the first power supply line is low and that of a light emitting element is high, the current controlling TFT is an N channel type. Therefore, the source electrode and the first power supply line are connected. Therefore, the capacitor element can be provided between the gate electrode and a source electrode of the current controlling TFT, that is, the first power supply line. When the switching nil, the driving TFT, or the current controlling TFT has a high gate capacitance and leak current from each TFT is permissible, the capacitor element 808 is not necessarily provided.

One electrode of the driving TFT 801 is connected to the other electrode of the current controlling TFT, and the gate electrode thereof is connected to a second power supply line 806. The second power supply line 806 has a fixed electric potential. Therefore, a gate electric potential of the driving TFT can be fixed, and the driving TFT can be operated so that gate-source voltage Vgs is not changed by parasitic capacitance or wiring capacitance.

Then, the light emitting element 807 is connected to the other electrode of the driving TFT. In this embodiment mode, when an electric potential of the first power supply line is low and that of the light emitting element is high, a cathode of the light emitting element is connected to the drain electrode of the driving TFT. Therefore, it is preferable to sequentially laminate a cathode, an electroluminescent layer and an anode. In this way, in the case of the TFT that has an amorphous semiconductor film and is an N channel type, it is preferable to connect the drain electrode of the TFT to the cathode and to laminate EIL, ETL, EML, HTL, HIL, and the node in this order.

Hereinafter, operation of such a pixel circuit is described.

When the scanning line 805 is selected and the switching TFT is turned ON, charges begin to be stored in the capacitor element 808. The charges are stored in the capacitor element 808 until they become equal to gate-source voltage of the current controlling TFT. When they are equal, the current controlling TFT is turned ON, and then, the driving TFT that is serially connected thereto is turned ON. At this time, the gate potential of the driving TFT is fixed. Therefore, constant gate-source voltage Vgs which does not depend on the parasitic capacitance or the wiring capacitance can be applied to the light emitting element. In other words, current by the constant gate-source voltage Vgs can be supplied.

Since the light emitting element is a current driving type element, it is preferable to employ analog driving when characteristic variation of the TFT in a pixel, specifically, Vth variation is small. As in this embodiment mode, the TFT having an amorphous semiconductor film has small characteristics variation; therefore, analog driving can be employed. On the other hand, also in the case of digital driving, current at a constant value can be supplied to the light emitting element by operating the driving TFT in a saturation region (a region satisfying |Vgs-Vth|<Vds|).

FIG. 9B shows an example of a top view of a pixel portion having the above equivalent circuit. Note that the cross-section taken along C-C′ of FIG. 9B corresponds to the cross-sectional view shown in FIG. 10.

A gate electrode, a scanning line (also, referred to as a gate wiring), and a second power supply line of each TFT are formed by an ink jet method or a sputtering method. It is preferable that the wirings are formed with the manufacturing apparatus shown in FIG. 1 or 2, thereby enhancing the productivity.

A first electrode 810 of the light emitting element 807 is formed over a gate insulating film. A source wiring, a drain wiring, a signal line and a first power supply line are formed by an ink-jet method or a sputtering method. It is preferable that the wirings are also formed with the manufacturing apparatus shown in FIG. 1 or 2, thereby enhancing the productivity.

The capacitor element 808 includes the gate wiring and the source and drain wirings which are formed with the gate insulating film therebetween. The channel width (W) of the driving TFT may be designed to be wide, since the driving TFT includes an amorphous semiconductor film.

The active matrix light-emitting device like this is effective because a TFT is provided for every pixel and thus it can be driven with low voltage, when a pixel density is increased per unit area.

This embodiment mode can be freely combined with Embodiment Modes 1 to 5.

An interlayer insulating film may be formed to increase planarity by using the structure shown in FIG. 7C of Embodiment Mode 5, although the structure shown in FIG. 7A of Embodiment Mode 5 is described in this embodiment mode. When the planarity is increased, voltage can be applied to the electroluminescent layer uniformly, which is preferable.

### Embodiment Mode 8

Embodiment Mode 8 shows a structure of a display panel obtained in Embodiment Mode 6 or 7

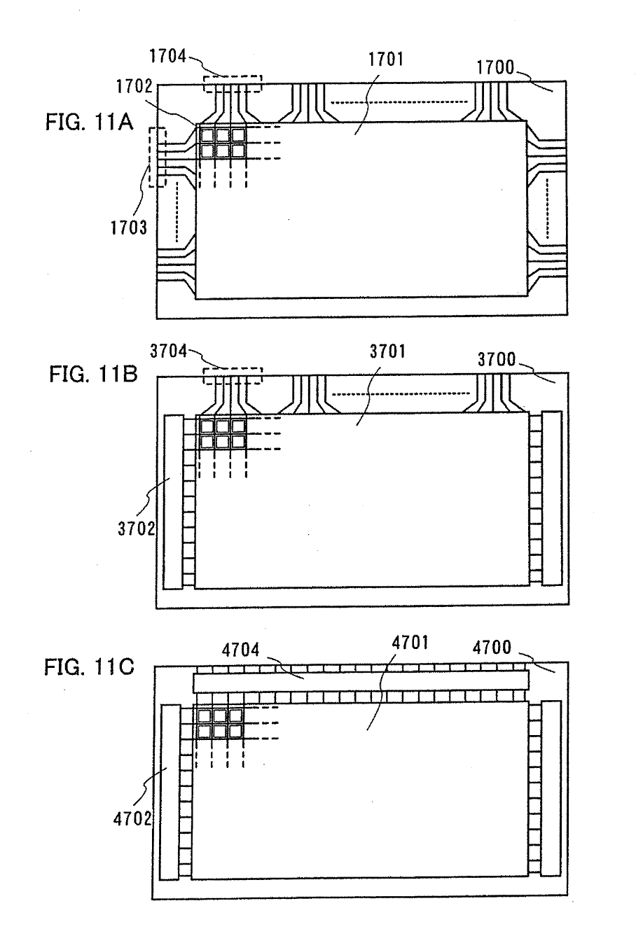

FIG. 11A shows a top view of a structure of a display panel as one example. A pixel portion 1701 in which pixels 1702 are arranged in matrix, a scanning line side input terminal 1703, and a signal line side input terminal 1704 are formed on a substrate 1700 having an insulating surface. The number of pixels may be provided according to various standards. The number of pixels of XGA may be 1024×768×3 (RGB), that of UXGA may be 1600×1200×3 (RGB), and that of a full-speck high vision may be 1920×1080×3 (RGB).

The pixels 1702 are arranged in matrix by intersecting a scanning line extended from the scanning line side input terminal 1703 with a signal line extended from the signal line side input terminal 1704. Each of the pixels 1702 is provided with a switching element and a pixel electrode connected thereto. A typical example of the switching element is a TFT. A gate electrode of a TFT is connected to the scanning line, and a source or drain thereof is connected to the signal line; therefore, each pixel can be controlled independently by a signal inputted from outside.

A TFT comprises a semiconductor layer, a gate insulating film, and a gate electrode as main component parts. Wiring layers connected with source and drain regions formed in the semiconductor layer are included too.

In this embodiment mode, dots containing a conductive material in a solvent are dropped and a gas is blown by a blowing means to form a gate electrode or a scanning line using a manufacturing apparatus using a droplet-discharging method shown in FIG. 1 or 2. In addition, a lead wiring or a terminal electrode to be connected to the scanning line side input terminal 1703 and the signal line side input terminal 1704 is formed with the manufacturing apparatus using a droplet-discharging method shown in FIGS. 1 and 2. After a conductive layer is formed by a droplet-discharging method using silver as a conductive material first, it may be plated with copper or the like. Plating may be conducted by an electroplating method or a chemical (electroless) electroplating method.

FIG. 11A shows a structure of a display panel in which input of a signal to the scanning line and signal line is controlled by an external driver circuit, but a driver IC may be mounted on the substrate by a COG method. As another mounting mode, a TAB (Tape Automated Bonding) method may be employed. The driver IC may be formed on a single-crystal semiconductor substrate or may be formed using a TFT on a glass substrate.

When a TFT provided in a pixel is formed from SAS, a scanning line driver circuit 3702 can be integrated on a substrate 3700 as shown in FIG. 11B. In FIG. 11B, a pixel portion 3701 is controlled by an external driver circuit connected to a signal line side input terminal 3704 as in FIG. 11A.

When the TFT provided in a pixel is formed using a polycrystal (micro crystal) semiconductor, a single-crystal semiconductor or the like that has a high mobility, a pixel portion 4701, a scanning line driver circuit 4702, and a signal line driver circuit 4704 can be integrated on a substrate 4700 in FIG. 11C.

This embodiment mode can be freely combined with Embodiment Modes 1 to 6.

### Embodiment Mode 9

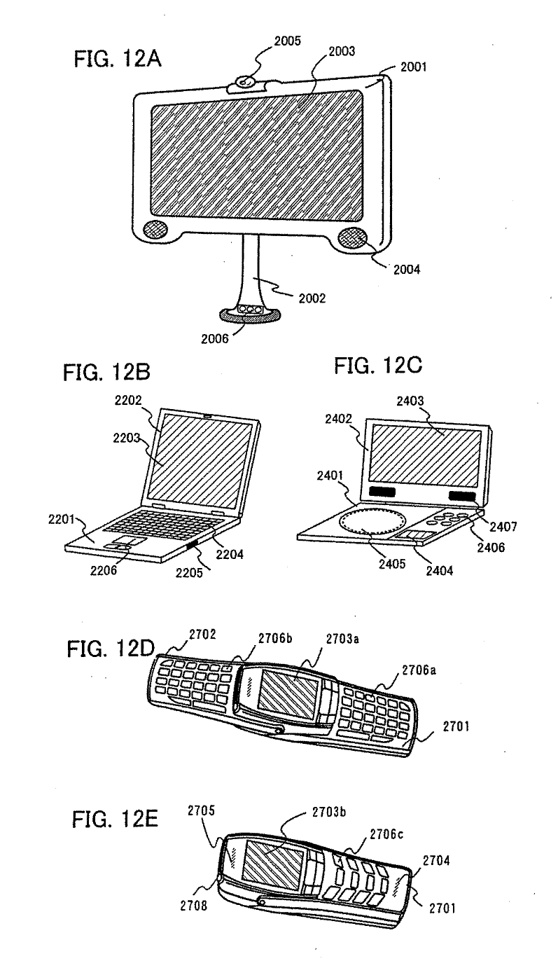

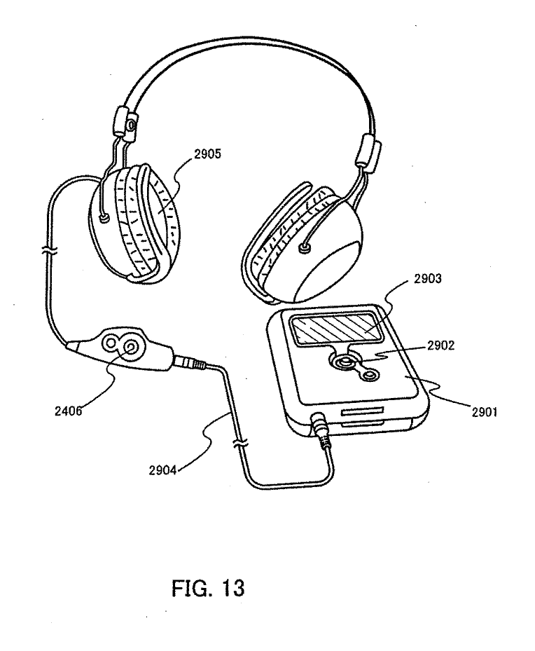

As semiconductor devices and electronic devices of the present invention, the flowing examples are given: a camera such as a video camera or a digital camera, a goggles-type display (head mount display), a navigation system, a sound reproduction device (a car audio equipment, an audio set and the like), a personal computer, a game machine, a portable information terminal (a mobile computer, a cellular phone, a portable game machine, an electronic book, or the like), an image-playback device including a recording medium (more specifically, a device which includes a display for reproducing a recording medium such as a digital versatile disc (DVD) and for displaying the reproduced image) and the like. FIGS. 12A to 12E and FIG. 13 show various specific examples of such electronic devices.

FIG. 12A illustrates a large display device having a 22- to 50-inch large screen including a casing 2001, a support table 2002, a display portion 2003, a speaker portion 2004, an imaging portion 2005, a video input terminal 2006, and the like. The display device includes all of the display devices for displaying information, such as display devices of a personal computer and a receiver of TV broadcasting. The display device includes an electrode or a wiring formed by a droplet-discharging method described in the above described embodiment modes. Further, the display portion 2003 is formed by a method in which a plurality of panels are formed from one substrate (gang printing); and therefore manufacturing cost of the large display device can be reduced.

FIG. 12B illustrates a personal computer including a main body 2201, a casing 2202, a display portion 2203, a key board 2204, an external connecting port 2205, a pointing mouse 2206, and the like. The personal computer includes an electrode or a wiring formed by a droplet-discharging method described in the above described embodiment modes. Further, the display portion 2203 is formed by a method in which a plurality of panels are formed from one substrate (gang printing); and therefore manufacturing cost of the personal computer can be reduced.

FIG. 12C illustrates a portable image-playback device including a recording medium (specifically, a DVD player) comprising a main body 2401, a casing 2402, a display portion A 2403, a display portion B 2404, a recording medium (DVD and the like) loading portion 2405, an operation key 2406, a speaker portion 2407, and the like. The display portion A 2403 displays mainly image information, whereas the display portion B 2404 displays mainly character information. The image-playback device including a recording medium includes a domestic game machine and the like. The image-playback device includes an electrode or a wiring formed by a droplet-discharging method described in the above described embodiment modes. Further, the display portions A 2403 and B 2404 are formed by a method in which a plurality of panels are formed from one substrate (gang printing); and therefore manufacturing cost of the image-playback device can be reduced.

FIG. 12D is a perspective view of a portable information terminal, and FIG. 12E is a perspective view illustrating a state in which the portable information terminal is folded to be used as a cellular phone. In the case of FIG. 12D, like a keyboard, a user operates an operation key 2706a with a finger of his/her right hand while operating an operation key 2706b with a finger of his/her let hand. The portable information terminal includes an electrode or a wiring formed by a droplet-discharging method described in the above described embodiment modes. Further, the display portions 2703a is formed by a method in which a plurality of panels are formed from one substrate (gang printing); and therefore manufacturing cost of the portable information terminal can be reduced.

As shown in FIG. 12E, in the case of being folded, a voice input portion 2704, a voice output portion 1705, an operation key 2705c, an antenna 2708, and the like are used while holding a main body 2701 and a casing 2702 with one hand. The portable information terminal shown in FIGS. 12D and 12E has a high-definition display portion 2703a mainly for displaying images and characters laterally and a display portion 2703b for displaying them vertically.

FIG. 13 shows a portable music-playback device provided with a recording medium, which includes a main body 2901, a display portion 2903, a recording medium loading portion (such as a card type memory), operation keys 2902 and 2906, and a speaker portion 2905 of a headphone connected to a connection cord 2904, and the like. The portable music-playback device includes an electrode or a wiring formed by a droplet-discharging method described in the above described embodiment modes. Further, the display portions 2903 is formed by a method in which a plurality of panels are formed from one substrate (gang printing); and therefore manufacturing cost of the portable music-playback device can be reduced.

This embodiment mode can be freely combined with Embodiment Modes 1 to 7.

According to the present invention, a pattern-forming apparatus suitable for a lager substrate in mass-producing can be realized. In addition, the tact time for manufacturing a semiconductor device can be shortened with a pattern-forming apparatus using a droplet-discharging method according to the present invention.

What is claimed is:

1. A method of manufacturing an active matrix display device, the method comprising:
disposing a substrate in a treatment chamber;
forming a conductive pattern for a gate electrode of a thin film transistor by discharging droplets containing a pattern-forming material from a first nozzle onto the substrate in the treatment chamber;
blowing gas from a second nozzle for controlling a flight-trajectory of the discharged droplets;
discharging the gas from the treatment chamber through an exhaust duct while discharging the droplets;
forming a gate insulating film over the gate electrode;
forming a semiconductor film over the gate insulating film;
forming a source electrode and a drain electrode in electrical contact with the semiconductor film; and
forming a pixel electrode in electrical contact with one of the source electrode and the drain electrode.

2. The method according to claim 1, wherein, in the treatment chamber, the second nozzle is located between the first nozzle and the exhaust duct.

3. The method according to claim 1, further comprising a step of heating the substrate during discharging the droplets.

4. The method according to claim 1, wherein the active matrix display device is a liquid crystal device.

5. The method according to claim 1, wherein the active matrix display device is a light emitting device.

6. A method of manufacturing an active matrix display device, the method comprising:
disposing a substrate in a treatment chamber;
forming a conductive pattern for a gate electrode of a thin film transistor by discharging droplets containing a pattern-forming material from a first nozzle onto the substrate in the treatment chamber;
blowing gas from a second nozzle for controlling a flight-trajectory of the discharged droplets;
discharging the gas from the treatment chamber through an exhaust duct while discharging the droplets;
baking the conductive pattern over the substrate;
forming a gate insulating film over the gate electrode;
forming a semiconductor film over the gate insulating film;
forming a source electrode and a drain electrode in electrical contact with the semiconductor film; and
forming a pixel electrode in electrical contact with one of the source electrode and the drain electrode.

7. The method according to claim 6, wherein, in the treatment chamber, the second nozzle is located between the first nozzle and the exhaust duct.

8. The method according to claim 6, further comprising a step of heating the substrate during discharging the droplets.

9. The method according to claim 6, wherein the active matrix display device is a liquid crystal device.

10. The method according to claim 6, wherein the active matrix display device is a light emitting device.

11. The method according to claim 6, wherein the conductive pattern is baked in a heating chamber connected to the treatment chamber.

12. A method of manufacturing an active matrix display device, the method comprising:
disposing a substrate in a treatment chamber;
forming a conductive pattern for a wiring of a thin film transistor by discharging droplets containing a pattern-forming material from a first nozzle onto the substrate in the treatment chamber;
blowing gas from a second nozzle for controlling a flight-trajectory of the discharged droplets;
discharging the gas from the treatment chamber through an exhaust duct while discharging the droplets; and
forming a pixel electrode in electrical contact with the thin film transistor.

13. The method according to claim 12, wherein, in the treatment chamber, the second nozzle is located between the first nozzle and the exhaust duct.

14. The method according to claim 12, further comprising a step of heating the substrate during discharging the droplets.

15. The method according to claim 12, wherein the active matrix display device is a liquid crystal device.

16. The method according to claim 12, wherein the active matrix display device is a light emitting device.

17. The method according to claim 12, further comprising a step of baking the conductive pattern.
